(19) United States
(12) Patent Application Publication
(10) Pub. No.: US 2025/0024655 A1
(43) Pub. Date: Jan. 16, 2025

(54) HEXAGONAL DOUBLE-LAYER ULTRAWIDEBAND ELECTROMAGNETIC WAVE ABSORBER

(71) Applicants: Industry-university Cooperation of USW, Hwaseong-si (KR); Center for Advanced Meta-Materials, Daejeon (KR)

(72) Inventors: Yongjune KIM, Seoul (KR); Keon-Soo JANG, Suwon-si (KR); Kichul KIM, Daejeon (KR); Tae-In CHOI, Daejeon (KR); Hak-Joo LEE, Daejeon (KR)

(73) Assignees: Industry-university Cooperation of USW, Hwaseong-si (KR); Center for Advanced Meta-Materials, Daejeon (KR)

(21) Appl. No.: 18/770,686

(22) Filed: Jul. 12, 2024

(30) Foreign Application Priority Data
Jul. 13, 2023 (KR) 10-2023-0090945
Jul. 13, 2023 (KR) 10-2023-0090946

(51) Int. Cl. H05K 9/00

(52) U.S. Cl. CPC H05K 9/0088

(57) ABSTRACT

The provided is an ultra-wideband electromagnetic wave absorber having a hexagonal double layer structure, and in the ultra-wideband electromagnetic wave absorber, the first conductive pattern disposed on the top of the first dielectric layer and the second conductive pattern disposed on the top of the second dielectric layer are arranged in an up-down double layer structure, thereby expanding the electromagnetic wave absorption bandwidth, and even when applied to a corner or a curved structure forming 60° or 120° by hexagonal unit cells, the unit cells can be periodically arranged at the same interval. In addition, since dielectrics with a difference of less than 10% in dielectric constant in a vacuum state have a relatively low specific gravity, the overall weight can be made very light by using such dielectrics in the first dielectric layer and the second dielectric layer.

### CROSS-REFERENCE TO THE RELATED APPLICATIONS

This application is based upon and claims priority to Korean Patent Application Nos. 10-2023-0090945, filed on Jul. 13, 2023, and 10-2023-0090946, filed on Jul. 13, 2023, the entire contents of which are incorporated herein by reference.

### TECHNICAL FIELD

The present invention relates to an electromagnetic wave absorber, and more particularly, to an absorber capable of absorbing electromagnetic waves in an ultra-wide band.

### BACKGROUND

Metamaterial absorber, one of the electromagnetic wave absorbers, is an electromagnetic wave absorber based on a structure consisting of a conductive pattern composed of carbon, indium tin oxide (ITO), silver nanowire, etc., a relatively thin dielectric layer, and a metal reflective layer. Metamaterial absorbers can dramatically lower electromagnetic wave reflectance not only by using impedance matching with air, but also by using the high ohmic loss occurring in the pattern.

Metamaterial absorbers have thin and light advantages over existing material-based electromagnetic wave absorbers such as ferrite using magnetic hysteresis loss and carbon composites using resistance loss, but they have limitations in that perfect electromagnetic wave absorption properties are realized only when conductive patterns at the top of the dielectric layer are arranged periodically at equal intervals. Therefore, in the case of a metamaterial absorber with an existing square unit cell, it is difficult to apply it to a three-dimensional corner structure or curved shape that is difficult to arrange periodically due to the staggering between unit cells. Here, the unit cell indicates a unit that composes the periodic array of it. In addition, metamaterial absorbers using single-layer conductive patterns face limitations that make it difficult to expand the absorption bandwidth.

The inventors of the present invention have made research efforts to solve the problems of the metamaterial absorber of the related art. After much effort, we have completed an ultra-wideband electromagnetic wave absorber with a hexagonal double-layer structure that can not only expand the bandwidth of the absorber but also dramatically lower the electromagnetic wave reflectance by stacking two patterns with a hexagonal unit cell composed of hexagonal conductive tiles, and can make relatively small hexagonal cells by constructing conductive patterns with rhombic conductive tiles.

### SUMMARY

### Technical Problem

The present invention is directed to provide an ultra-wideband electromagnetic wave absorber with a dramatically expanded bandwidth compared to conventional metamaterial absorbers.

In addition, it is directed to provide an ultra-wideband electromagnetic wave absorber having a hexagonal unit cell which can be periodically arranged on a three-dimensional corner structure or curved surface.

In addition, it is directed to providing an ultra-wideband electromagnetic wave absorber that can significantly reduce the size and thickness of a unit cell by using rhombic conductive tiles.

Meanwhile, other aspects not specified of the present invention will be additionally contemplated within the range that can be easily inferred from the following detailed description and effects thereof.

### Technical Solution

An ultra-wideband electromagnetic wave absorber having hexagonal unit cells according to an exemplary embodiment of the present invention includes a first dielectric layer of having the same hexagonal unit cell shape; a first conductive pattern formed on the upper surface of the first dielectric layer; a second dielectric layer located below the first dielectric layer and having the same hexagonal unit cell shape as the first dielectric layer; a second conductive pattern formed between the first dielectric layer and the second dielectric layer; and a reflective layer formed on the lower surface of the second dielectric layer.

A sheet resistance of the first conductive pattern may be greater than a sheet resistance of the second conductive pattern.

The first conductive pattern and the second conductive pattern may be composed of carbon, ITO (Indium Tin Oxide), or silver nanowire.

The first conductive pattern and the second conductive pattern may be formed by a combination of a plurality of conductive hexagonal tiles and blank hexagonal tiles.

The first conductive pattern and the second conductive pattern may be formed by being arranged axially symmetrically with respect to a diagonal axis connecting opposing vertices of a hexagonal unit cell.

Only a portion of the first conductive pattern and the second conductive pattern may overlap in a direction perpendicular to the first dielectric layer and the second dielectric layer.

The first conductive pattern may include a first pattern, a second pattern, and a third pattern in a direction away from the center of the first dielectric layer, the second conductive pattern may include a fourth pattern, a fifth pattern, and a sixth pattern in a direction away from the center of the second dielectric layer, the first pattern and the second pattern, and the fourth pattern and the fifth pattern may be formed in overlapping regions based on the vertical direction of the first dielectric layer and the second dielectric layer, respectively, and the fifth pattern and the sixth pattern may be respectively formed in regions that do not overlap based on the vertical direction of the first dielectric layer and the second dielectric layer.

The length of one side of the first dielectric layer and the second dielectric layer may be smaller than the length of the wavelength of the lowest frequency of the absorbed electromagnetic wave.

The ultra-wideband electromagnetic wave absorber may further include a protective layer formed on the top of the first conductive pattern.

The reflective layer may be made of metal.

The difference between a dielectric constant of the first and the second dielectric layers and a dielectric constant of the air may be less than 10% based on the dielectric constant of the air.

The first conductive pattern and the second conductive pattern may be formed by a combination of a plurality of conductive rhombic tiles and blank rhombic tiles.

The size of a blank region formed in the first conductive pattern or the second conductive pattern may be greater than or equal to a width between two opposite sides of the blank rhombic tile.

The size of a conductive region formed in the first conductive pattern or the second conductive pattern may be greater than or equal to a width between two opposite sides of the conductive rhombic tile.

The first conductive pattern and the second conductive pattern may have a blank region which is a region where blank rhombic tiles of the first conductive pattern and the second conductive pattern overlap in a direction perpendicular to the first dielectric layer and the second dielectric layer.

The thickness of the second dielectric layer may be greater than or equal to the thickness of the first dielectric layer.

The overall thickness of the ultra-wideband electromagnetic wave absorber may be 0.11 times or less of the wavelength of the lowest frequency in the target frequency band. The protective layer may be made of tempered glass.

The protective layer may further include a foam material located between the upper end of the first conductive pattern and the tempered glass.

### Advantageous Effects

According to the present invention, the bandwidth limitation when using a single-layer absorber can be overcome by using a structure in which two conductive patterns are stacked.

In addition, by using a hexagonal double-layer conductive pattern, the unit cells can be arranged periodically at the same interval even when applied to a corner structure or curved shape forming 60° or 120°.

In addition, since dielectrics with a difference of less than 10% in dielectric constant in a vacuum state have a relatively low specific gravity, they can be manufactured very lightly by including such a dielectric layer.

In addition, the size of the entire cell can be reduced by forming a conductive pattern using rhombic tiles.

Furthermore, two layers of conductive patterns can be used to lower the reflectance to less than −10 dB in the ultra-wideband frequency range of 1 to 12.1 GHz, and a relative bandwidth of 169.5% can be achieved.

In addition, even after combining a protective layer that can protect the pattern, the reflectance can be lowered to less than −10 dB in the relative bandwidth of 153.5% in the 1.6 to 12.1 GHz range, thereby increasing the durability of the ultra-wideband electromagnetic wave absorber while maintaining wideband absorption performance.

Therefore, since the ultra-wideband electromagnetic wave absorber according to the present invention can absorb the ultra-wideband radar signal, the cross-sectional area of the radar operating in various bands can be efficiently reduced, and it can be applied to a corner or curved structure and has a very light advantage, so it can be used as a stealth material for mobile weapon systems such as fighter jets, drones, and ships.

In the meantime, even if there is an effect not explicitly specified herein, it is added that the effects expected by the technical features of the present invention and described effects and provisional effects thereof in the following specification are regarded as described in the specification of the present invention.

### BRIEF DESCRIPTION OF THE DRAWINGS

FIG. 1 is a cross-sectional view of a unit cell of an ultra-wideband electromagnetic wave absorber according to a preferred embodiment of the present invention.

FIG. 2 is a perspective view of a unit cell of an ultra-wideband electromagnetic wave absorber according to a preferred embodiment of the present invention.

FIGS. 3A and 3B show a more detailed structural view of a unit cell of an ultra-wideband electromagnetic wave absorber according to a preferred embodiment of the present invention.

FIGS. 4A and 4B show a plan view and a perspective view of a unit cell of an ultra-wideband electromagnetic wave absorber according to a preferred embodiment of the present invention.

FIG. 5 shows a simulation result of reflectance of an ultra-wideband electromagnetic wave absorber according to a preferred embodiment of the present invention.

FIG. 6 is a cross-sectional view of a unit cell of an ultra-wideband electromagnetic wave absorber according to another preferred embodiment of the present invention.

FIG. 7 is a perspective view of a unit cell of an ultra-wideband electromagnetic wave absorber according to another preferred embodiment of the present invention.

FIG. 8 shows a simulation result of reflectance of an ultra-wideband electromagnetic wave absorber according to another preferred embodiment of the present invention.

FIG. 9 is a cross-sectional view of a unit cell of an ultra-wideband electromagnetic wave absorber according to yet another preferred embodiment of the present invention.

FIG. 10 is a perspective view of a unit cell of an ultra-wideband electromagnetic wave absorber according to yet another preferred embodiment of the present invention.

FIGS. 11A-11C show a plan view of an ultra-wideband electromagnetic wave absorber according to yet another preferred embodiment of the present invention.

FIG. 12 shows an example of a minimum size blank region formed in a unit cell of an ultra-wideband electromagnetic wave absorber according to yet another preferred embodiment of the present invention.

FIG. 13 shows a simulation result of reflectance of an ultra-wideband electromagnetic wave absorber according to yet another preferred embodiment of the present invention.

FIG. 14 is a perspective view of a unit cell of an ultra-wideband electromagnetic wave absorber according to yet another preferred embodiment of the present invention.

FIGS. 15A-15C show a plan view of a unit cell of an ultra-wideband electromagnetic wave absorber according to yet another preferred embodiment of the present invention.

FIG. 16 shows an example of a minimum size conductive region formed in a unit cell of an ultra-wideband electromagnetic wave absorber according to yet another preferred embodiment of the present invention.

FIG. 17 shows a simulation result of reflectance of an ultra-wideband electromagnetic wave absorber according to yet another preferred embodiment of the present invention.

FIG. 18 is a cross-sectional view of a unit cell of an ultra-wideband electromagnetic wave absorber according to yet another preferred embodiment of the present invention.

FIG. 19 is a perspective view of a unit cell of an ultra-wideband electromagnetic wave absorber according to yet another preferred embodiment of the present invention.

FIGS. 20A-20C show a plan view of a unit cell of an ultra-wideband electromagnetic wave absorber according to yet another preferred embodiment of the present invention.

FIG. 21 shows a simulation result of reflectance of an ultra-wideband electromagnetic wave absorber according to yet another preferred embodiment of the present invention.

The accompanying drawings are exemplified by reference for understanding the technical idea of the present invention, and the scope of the present invention is not limited thereto.

### DETAILED DESCRIPTION OF THE EMBODIMENTS

Hereinafter, a configuration of the present invention guided by various embodiments of the present invention and effects resulting from the configuration will be described with reference to the drawings. In describing the present invention when it is determined that a detailed description of a related known function obvious to those skilled in the art may unnecessarily obscure the subject matter of the present invention, the detailed description thereof will be omitted.

Terms such as ‘first’ and ‘second’ may be used to describe various elements, but, the above elements should not be limited by the terms above. The above terms may be used only for the purpose of distinguishing one element from another. For example, without departing from the scope of the present invention, a ‘first element’ may be named a ‘second element’ and similarly, a ‘second element’ may also be named a ‘first element.’ In addition, expressions in the singular include plural expressions unless explicitly expressed otherwise in the context. Unless otherwise defined, terms used in the embodiments of the present invention may be interpreted as meanings commonly known to those of ordinary skill in the art.

Hereinafter, a configuration of the present invention guided by various embodiments of the present invention and effects resulting from the configuration will be described with reference to the drawings.

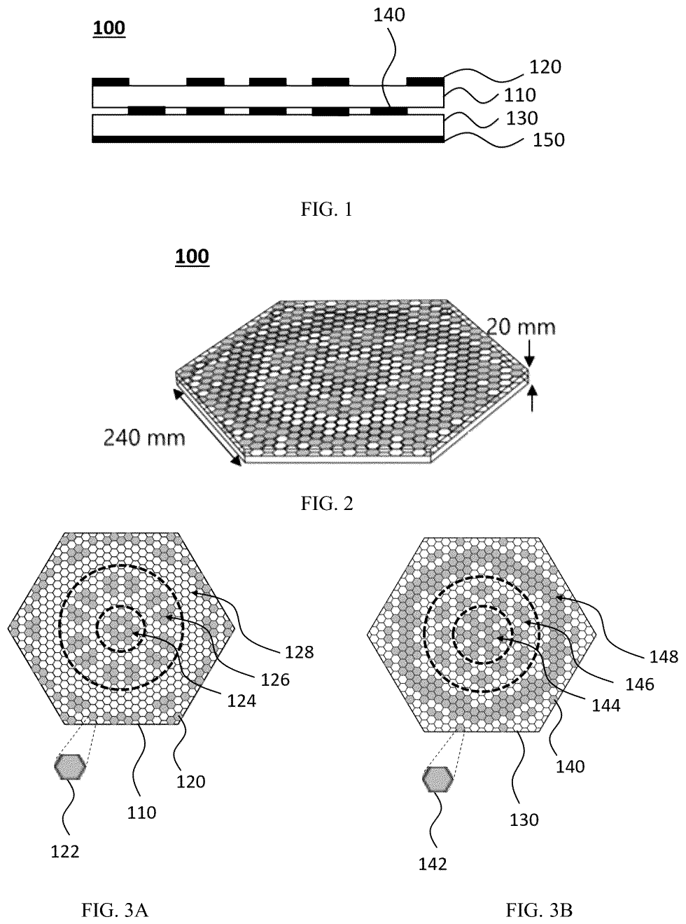

FIG. 1 is a cross-sectional view of a unit cell of an ultra-wideband electromagnetic wave absorber according to a preferred embodiment of the present invention.

The unit cell of the ultra-wideband electromagnetic wave absorber 100 according to an exemplary embodiment of the present invention includes a first dielectric layer 110, a first conductive pattern 120, a second dielectric layer 130, a second conductive pattern 140, and a reflective layer 150.

The first dielectric layer 110 may be formed of a substrate made of a foam material having a light weight having a hexagonal outer shell.

The first dielectric layer 110 may be made of a foam material that has a dielectric constant similar to that of air, a loss tangent of 0.0035, and a thickness of 10 mm, but is not limited thereto. The first dielectric layer 110 may be formed of a material having a dielectric constant having a difference of less than 10% based on the dielectric constant in a vacuum state, and may have, for example, a relative dielectric constant of 1.07.

The length of one side of the hexagonal unit cell of the first dielectric layer 110 may be designed to be smaller than the length corresponding to one wavelength based on the lowest frequency among the absorbed electromagnetic waves.

For example, in the case of an L band with a frequency band of 1 GHz to 2 GHz, the minimum frequency is 1 GHz and the corresponding wavelength is 300 mm, so the length of one side of the hexagonal unit cell of the first dielectric layer 110 may be designed to be less than 300 mm. In an embodiment, the length of one side of the hexagonal unit cell of the first dielectric layer 110 corresponding to the L band may be 240 mm corresponding to the 0.8 wavelength.

The first conductive pattern 120 is formed on the top of the first dielectric layer 110.

The first conductive pattern 120 may be formed by arranging a plurality of hexagonal tiles. The hexagonal tile may have a side of 10 mm.

The hexagonal tile may be filled with a conductive material, and examples of the conductive material include, but are not limited to, carbon, indium tin oxide (ITO), and silver nanowire.

The second dielectric layer 130 may be formed of a substrate made of a foam material having the same shape as the first dielectric layer 110 and a light weight having a hexagonal outer shell. In this case, the dielectric constant of the foam material has a difference of less than 10% compared to the dielectric constant in a vacuum state. For example, the relative dielectric constant of the second dielectric layer 130 may be 1.07.

The second dielectric layer 130 is located below the first dielectric layer 110.

Both the first dielectric layer 110 and the second dielectric layer 130 may have a thickness of 10 mm, and therefore, the total thickness of the ultra-wideband electromagnetic wave absorber 100 may be 20 mm, but is not limited thereto.

The second conductive pattern 140 is formed on the top of the second dielectric layer 130, and the reflective layer 150 is formed on the bottom of the second dielectric layer 130.

Like the first conductive pattern 120, the second conductive pattern 140 may also be composed of a plurality of hexagonal tiles, and the length of one side of the hexagonal tile may be 10 mm.

In an embodiment, the sheet resistance of the first conductive pattern 120 may be greater than the sheet resistance of the second conductive pattern 140. For example, the sheet resistance of the first conductive pattern 120 may be 100 Ω/sq, and the sheet resistance of the second conductive pattern 140 may be 50 Ω/sq.

The reflective layer 150 may be formed on the bottom of the second dielectric layer 130. The reflective layer 150 may be made of a metal material such as copper, gold, or silver, or a carbon fiber reinforced polymer, but is not limited thereto.

FIG. 2 is a perspective view of a unit cell of an ultra-wideband electromagnetic wave absorber according to a preferred embodiment of the present invention.

In the unit cell of the ultra-wideband electromagnetic wave absorber 100, it may be seen that the first conductive pattern 120 and the second conductive pattern 140 respectively positioned on the top of the first dielectric layer 110 and the second dielectric layer 130 have a double layer structure.

An example is shown that the distance between the first conductive pattern 120 and the second conductive pattern 140 is 10 mm, the overall thickness of the unit cell of the ultra-wideband electromagnetic wave absorber 100 is 20 mm, and one side is 240 mm.

FIGS. 3A and 3B show a more detailed structural view of a unit cell of an ultra-wideband electromagnetic wave absorber according to a preferred embodiment of the present invention.

FIG. 3A shows an example of the first dielectric layer 110, which is an upper layer, and the first conductive pattern 120 formed thereon, and FIG. 3B shows an example of the second dielectric layer 130, which is a lower layer, and the second conductive pattern 140 formed thereon.

The first conductive pattern 120 is formed by arranging a plurality of hexagonal tiles 122. The tile 122 is characterized in that it is arranged axially symmetrically with respect to an axis connecting opposing vertices of the hexagonal unit cell forming the exterior of the first dielectric layer 110.

The second conductive pattern 140 is also formed by arranging a plurality of hexagonal tiles 142. The tile 142 is characterized in that it is arranged axially symmetrically with respect to an axis connecting opposing vertices of the hexagonal unit cell forming the exterior of the second dielectric layer 130.

The first conductive pattern 120 may be sequentially composed of three regions of a first pattern 124, a second pattern 126, and a third pattern 128 from the center to the outside, and the second conductive pattern 140 may be also sequentially composed of three regions of a fourth pattern 144, a fifth pattern 146, and a sixth pattern 148 from the center to the outside.

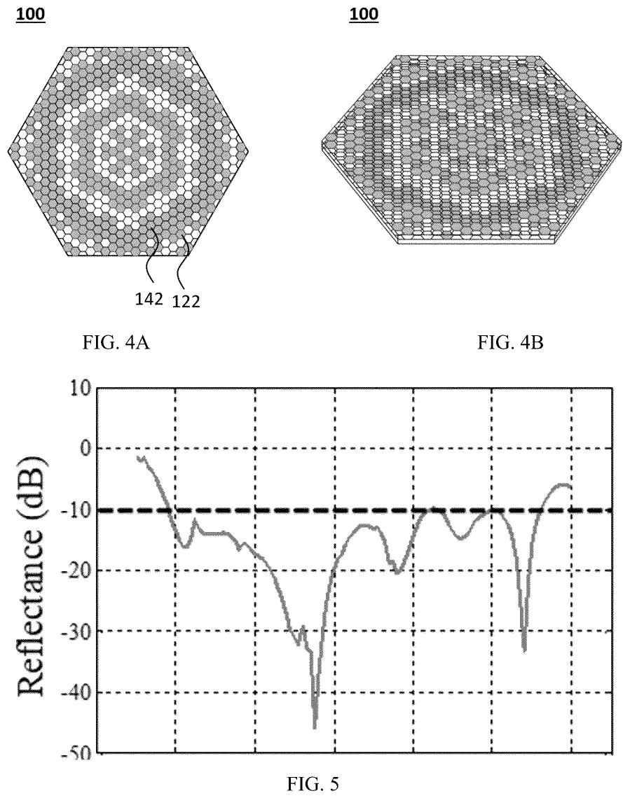

FIGS. 4A and 4B show a plan view and a perspective view showing the arrangement of conductive patterns of a unit cell of an ultra-wideband electromagnetic wave absorber according to a preferred embodiment of the present invention.

FIG. 4A is a plan view showing the first conductive pattern 120 and the second conductive pattern 140 being overlapped, and FIG. 4B is a perspective view showing the first conductive pattern 120 and the second conductive pattern 140 being overlapped.

In FIGS. 4A and 4B, the thin-rimmed tile 122 forms the first conductive pattern 120, and the thick-rimmed tile 142 forms the second conductive pattern 140.

When checked in a direction perpendicular to the first conductive pattern 120 and the second conductive pattern 140, the first pattern 124 and the second pattern 126 of the first conductive pattern 120 and the fourth pattern 144 and the fifth pattern 146 of the second conductive pattern 140 may be overlapped in the vertical direction. The third pattern 128 of the first conductive pattern 120 and the sixth pattern 148 of the second conductive pattern 140 may be not overlapped each other. That is, the sixth pattern 148 of the second conductive pattern 140 may be arranged so as not to overlap in the vertical direction between the second pattern 126 and the third pattern 128 of the first conductive pattern 120.

FIG. 5 shows a simulation result of reflectance of an ultra-wideband electromagnetic wave absorber according to a preferred embodiment of the present invention.

It is a result of simulating the reflectance of electromagnetic waves from L band to X band for the ultra-wideband electromagnetic wave absorber 100 with a double layer structure according to an exemplary embodiment of the present invention.

In FIG. 5, from 1.85 GHz included in the L band to 11.2 GHz included in the X band, a bandwidth having a reflectance of −10 dB or less of the relative bandwidth of 143.3% may be seen.

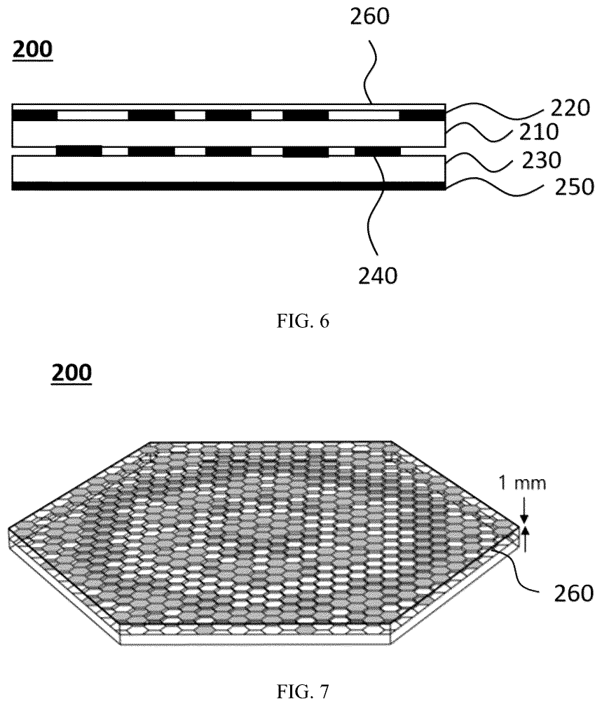

FIG. 6 is a cross-sectional view of a unit cell of an ultra-wideband electromagnetic wave absorber according to another preferred embodiment of the present invention.

The unit cell of the ultra-wideband electromagnetic wave absorber 200 according to another exemplary embodiment of the present invention may further include a protective layer 260 in addition to the first dielectric layer 210, the first conductive pattern 220, the second dielectric layer 230, the second conductive pattern 240, and the reflective layer 250.

The protective layer 260 may be formed of tempered glass or the like to maximize durability by protecting the absorber 200 from high temperature and humid environments or brine.

The protective layer 260 may be made of tempered glass having a relative dielectric constant of 4.6 and a loss tangent of 0.0012, but is not limited thereto.

FIG. 7 is a perspective view of a unit cell of an ultra-wideband electromagnetic wave absorber according to another preferred embodiment of the present invention.

It shows a perspective view of the unit cell of the ultra-wideband electromagnetic wave absorber 200 to which a protective layer 260 made of tempered glass or the like is added. The thickness of the protective layer 260 is 1 mm, but is not limited thereto.

FIG. 8 shows a simulation result of reflectance of an ultra-wideband electromagnetic wave absorber according to another preferred embodiment of the present invention.

It shows a reflectance simulation result for the ultra-wideband electromagnetic wave absorber 200 having a structure in which 1 mm of tempered glass is coupled to the upper portion of the first conductive pattern 220 as the protective layer 260.

It may be seen that the reflectance of −10 dB or less is maintained in a fairly wide band even after the protective layer 260 is coupled.

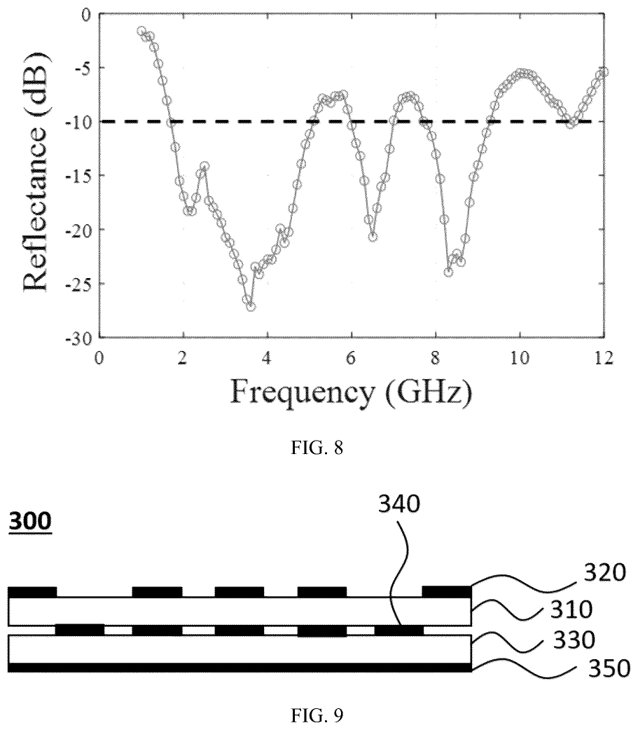

FIG. 9 is a cross-sectional view of a unit cell of an ultra-wideband electromagnetic wave absorber according to yet another preferred embodiment of the present invention.

The unit cell of the ultra-wideband electromagnetic wave absorber 300 according to an exemplary embodiment of the present invention includes a first dielectric layer 310, a first conductive pattern 320, a second dielectric layer 330, a second conductive pattern 340, and a reflective layer 350.

The first dielectric layer 310 may be formed of a substrate made of a foam material having a light weight having a hexagonal outer shell.

The first dielectric layer 310 may be made of a foam material that has a dielectric constant similar to that of air, a loss tangent of 0.0035, and a thickness of 10 mm, but is not limited thereto. The first dielectric layer 310 may be formed of a material having a dielectric constant having a difference of less than 10% based on the dielectric constant in a vacuum state, and may have, for example, a relative dielectric constant of 1.07.

The length of one side of the hexagonal unit cell of the first dielectric layer 310 may be designed to be smaller than the length corresponding to one wavelength based on the lowest frequency among the absorbed electromagnetic waves.

For example, it may be designed to be 43.35 mm corresponding to 0.25 wavelength based on 1.7 GHZ, the minimum frequency in a range with a reflectance of −10 dB or less, but is not limited thereto.

The first conductive pattern 320 is formed on the top of the first dielectric layer 310.

The first conductive pattern 320 may be formed by arranging a plurality of rhombic tiles.

The length of one side of the rhombic tile may be designed to be 2.89 mm, but is not limited thereto.

The first conductive pattern 320 may be formed by arranging a combination of rhombic conductive tiles and rhombic blank tiles.

The conductive tile may be filled with a conductive material, and examples of the conductive material include, but are not limited to, carbon, indium tin oxide (ITO), and silver nanowire.

The second dielectric layer 330 may be formed of a substrate made of a foam material having the same shape as the first dielectric layer 310 and a light weight having a hexagonal outer shell. In this case, the dielectric constant of the foam material has a difference of less than 10% compared to the dielectric constant in a vacuum state. For example, the relative dielectric constant of the second dielectric layer 330 may be 1.07.

The second dielectric layer 330 is located below the first dielectric layer 310.

Both the first dielectric layer 310 and the second dielectric layer 330 may have a thickness of 10 mm, and therefore, the total thickness of the ultra-wideband electromagnetic wave absorber 300 may be 20 mm, but is not limited thereto.

The second conductive pattern 340 is formed on the top of the second dielectric layer 330. That is, the second conductive pattern 340 is located between the first dielectric layer 310 and the second dielectric layer 330.

Like the first conductive pattern 320, the second conductive pattern 340 may also be composed of a plurality of rhombic tiles, and the length of one side of the rhombic tile may be 2.89 mm, but is not limited thereto. In addition, the size of the rhombic tile of the first conductive pattern 320 and the size of the rhombic tile of the second conductive pattern 340 may be different.

In an embodiment, the sheet resistance of the first conductive pattern 320 may be greater than the sheet resistance of the second conductive pattern 340. For example, the sheet resistance of the first conductive pattern 320 may be 100 Ω/sq, and the sheet resistance of the second conductive pattern 340 may be 25 Ω/sq.

The reflective layer 350 may be formed on the bottom of the second dielectric layer 330. The reflective layer 350 may be formed of a metal material such as copper, gold, or silver, but is not limited thereto.

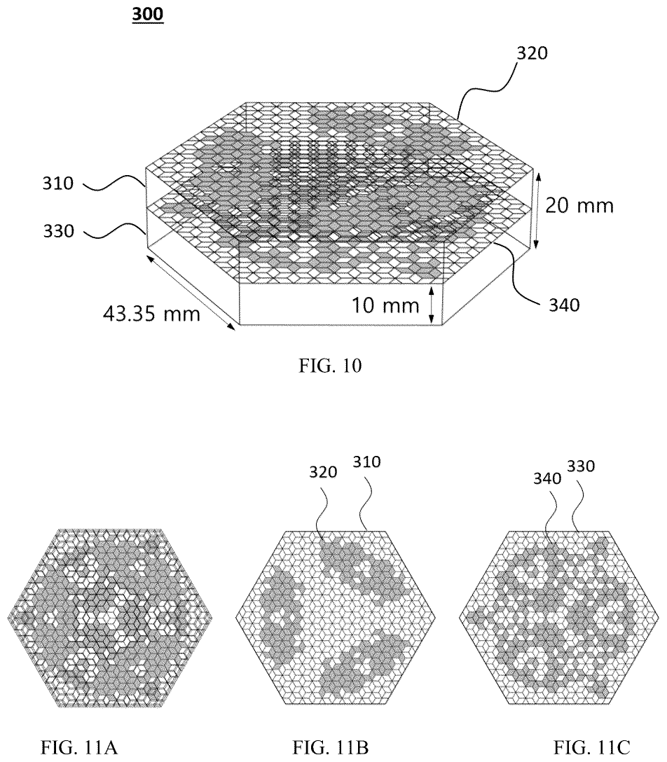

FIG. 10 is a perspective view of a unit cell of an ultra-wideband electromagnetic wave absorber according to yet another preferred embodiment of the present invention.

In the unit cell of the ultra-wideband electromagnetic wave absorber 300, it may be seen that the first conductive pattern 320 and the second conductive pattern 340 respectively positioned on the top of the first dielectric layer 310 and the second dielectric layer 330 have a double layer structure.

An example is shown that the distance between the first conductive pattern 320 and the second conductive pattern 340 is 10 mm, the overall thickness of the ultra-wideband electromagnetic wave absorber 300 is 20 mm, and one side of the hexagon is 43.35 mm.

FIGS. 11A-11C show a plan view of each layer of a unit cell of an ultra-wideband electromagnetic wave absorber according to yet another preferred embodiment of the present invention.

FIG. 11A shows an example in which the first conductive pattern 320 and the second conductive pattern 340 are formed by overlapping each other.

In the example where the first conductive pattern 320 and the second conductive pattern 340 overlap, it may be seen that a blank region exists inside the entire pattern as the blank portion of the first conductive pattern 120 and the blank portion of the second conductive pattern 140 overlap.

FIG. 11B shows an example of the first dielectric layer 310, which is an upper layer, and the first conductive pattern 320 formed thereon, and FIG. 11C shows an example of the second dielectric layer 330, which is a lower layer, and the second conductive pattern 340 formed thereon.

The first conductive pattern 320 is formed by arranging a plurality of rhombic conductive tiles. The conductive tile is characterized in that it is arranged axially symmetrically with respect to an axis connecting opposing vertices of the hexagonal unit cell forming the exterior of the first dielectric layer 310.

The second conductive pattern 340 is also formed by arranging a plurality of rhombic conductive tiles. The rhombic tile is characterized in that it is arranged axially symmetrically with respect to an axis connecting opposing vertices of the hexagonal unit cell forming the exterior of the second dielectric layer 330.

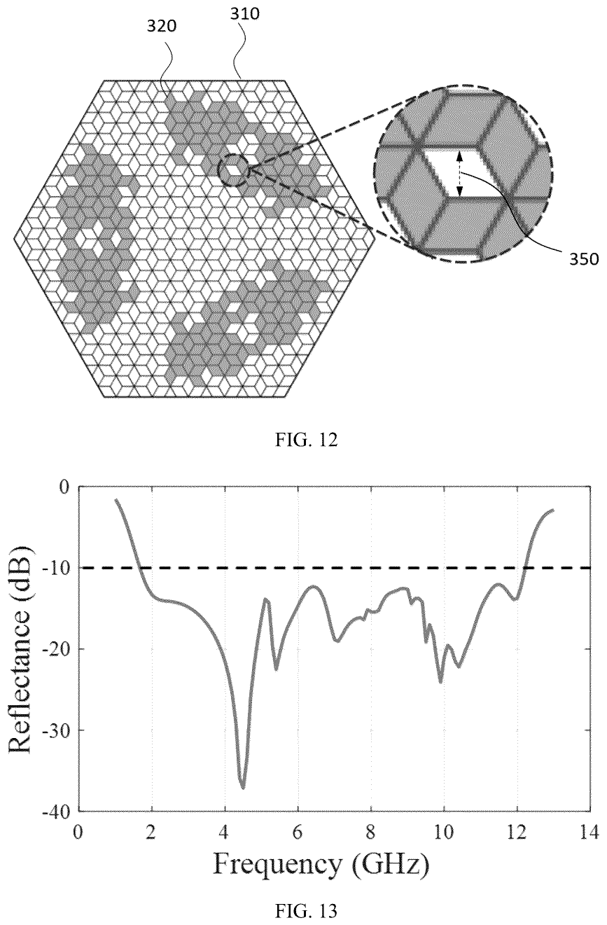

FIG. 12 shows an example of a minimum size blank region formed in a unit cell of an ultra-wideband electromagnetic wave absorber according to yet another preferred embodiment of the present invention.

FIG. 12 is an enlarged view of the blank region in FIG. 11B, and shows an example in which the blank region is formed in a rhombus shape with a minimum size.

According to the present invention, a blank region formed between conductive regions thus has a characteristic greater than or equal to a width 350 between two opposite sides of a rhombic blank region formed to have a minimum size.

FIG. 13 shows a simulation result of reflectance of an ultra-wideband electromagnetic wave absorber according to yet another preferred embodiment of the present invention.

It is a result of simulating the reflectance of electromagnetic waves from L band to X band vertically incident on the ultra-wideband electromagnetic wave absorber 300 with a double layer structure according to an exemplary embodiment of the present invention.

In FIGS. 11A-11C, from 1.7 GHZ included in the L band to 12.2 GHz included in the X band, a bandwidth having a reflectance of −10 dB or less of the relative bandwidth of 151.1% may be seen.

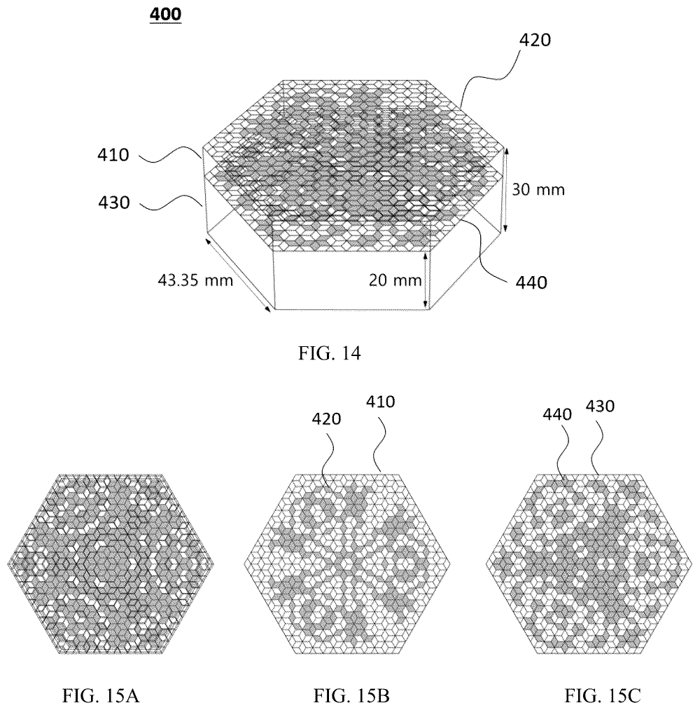

FIG. 14 is a perspective view of a unit cell of an ultra-wideband electromagnetic wave absorber according to yet another preferred embodiment of the present invention.

The unit cell of the ultra-wideband electromagnetic wave absorber 400 according to another exemplary embodiment of the present invention may differently set the thickness of the first dielectric layer 410 and the thickness of the second dielectric layer 430 in order to further expand a bandwidth having a reflectance of −10 dB or less.

In an example, the thickness of the second dielectric layer 430 may be set to be thicker than the thickness of the first dielectric layer 410.

In the example of FIG. 14, the thickness of the first dielectric layer 410 is 10 mm, and the thickness of the second dielectric layer 430 is set to 20 mm, and thus the thickness of the entire ultra-wideband electromagnetic wave absorber 400 is 30 mm.

In this case, the sheet resistance of the first conductive pattern 420 may be greater than the sheet resistance of the second conductive pattern 440. For example, the sheet resistance of the first conductive pattern 420 may be 100 Ω/sq, and the sheet resistance of the second conductive pattern 440 may be 25 Ω/sq.

By making the thickness of the second dielectric layer 430 thicker than the thickness of the first dielectric layer 410, a range of frequencies having a reflectance of −10 dB or less may be further expanded.

When the thickness of the first dielectric layer 410 is set to 10 mm and the thickness of the second dielectric layer 430 is set to 20 mm, the lowest frequency having a reflectance of −10 dB or less is lowered to 1 GHz. In this case, the total thickness of the ultra-wideband electromagnetic wave absorber 400, 30 mm, corresponds to 0.1 wavelength based on 1 GHz, which is the lowest frequency, and the length of one side of the hexagonal unit cell corresponds to 0.14 wavelength.

FIGS. 15A-15C show a plan view of a unit cell of an ultra-wideband electromagnetic wave absorber according to yet another preferred embodiment of the present invention.

FIG. 15A shows an example in which the first conductive pattern 420 and the second conductive pattern 440 are formed by overlapping each other.

In the example where the first conductive pattern 420 and the second conductive pattern 440 overlap, it may be seen that a blank region exists inside the entire pattern as the blank portion of the first conductive pattern 420 and the blank portion of the second conductive pattern 440 overlap.

FIG. 15B shows an example of the first dielectric layer 410, which is an upper layer, and the first conductive pattern 420 formed thereon, and FIG. 15C shows an example of the second dielectric layer 430, which is a lower layer, and the second conductive pattern 440 formed thereon.

The first conductive pattern 420 is formed by arranging a plurality of rhombic conductive tiles. The conductive tile is characterized in that it is arranged axially symmetrically with respect to an axis connecting opposing vertices of the hexagonal unit cell forming the exterior of the first dielectric layer 410.

The second conductive pattern 440 is also formed by arranging a plurality of rhombic conductive tiles. The rhombic tile is characterized in that it is arranged axially symmetrically with respect to an axis connecting opposing vertices of the hexagonal unit cell forming the exterior of the second dielectric layer 430.

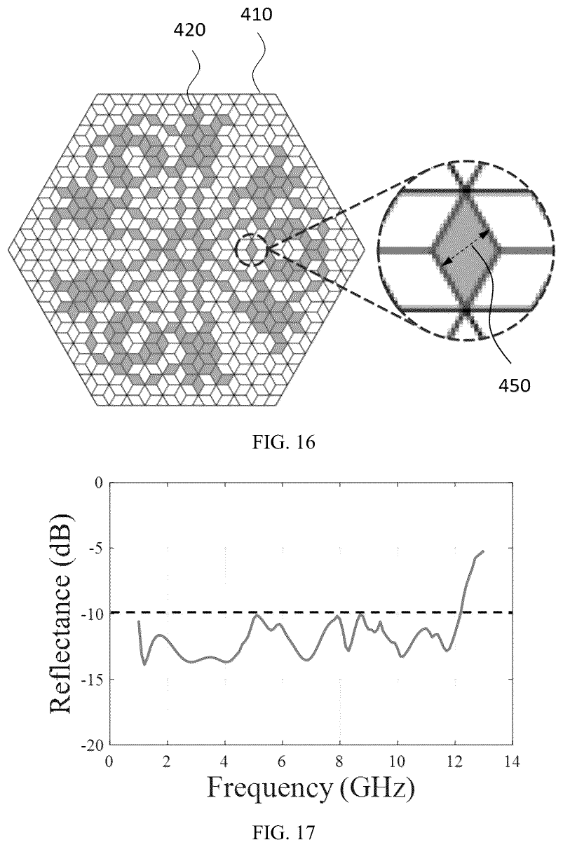

FIG. 16 shows an example of a minimum size conductive region formed in a unit cell of an ultra-wideband electromagnetic wave absorber according to yet another preferred embodiment of the present invention.

FIG. 16 is an enlarged view of the conductive region in FIG. 15B, and shows an example in which the conductive region is formed in a rhombus shape with a minimum size.

According to the present invention, a conductive region formed by a rhombic tile thus has a characteristic greater than or equal to a width 450 between two opposite sides of a rhombic tile formed to have a minimum size.

FIG. 17 shows a simulation result of reflectance of an ultra-wideband electromagnetic wave absorber according to another preferred embodiment of the present invention.

It is a result of simulating the reflectance of electromagnetic waves vertically incident on the ultra-wideband electromagnetic wave absorber 400 with a double layer structure according to an exemplary embodiment of the present invention.

It can be seen that the frequency range with a reflectance of −10 dB or less has been extended to 1 GHz.

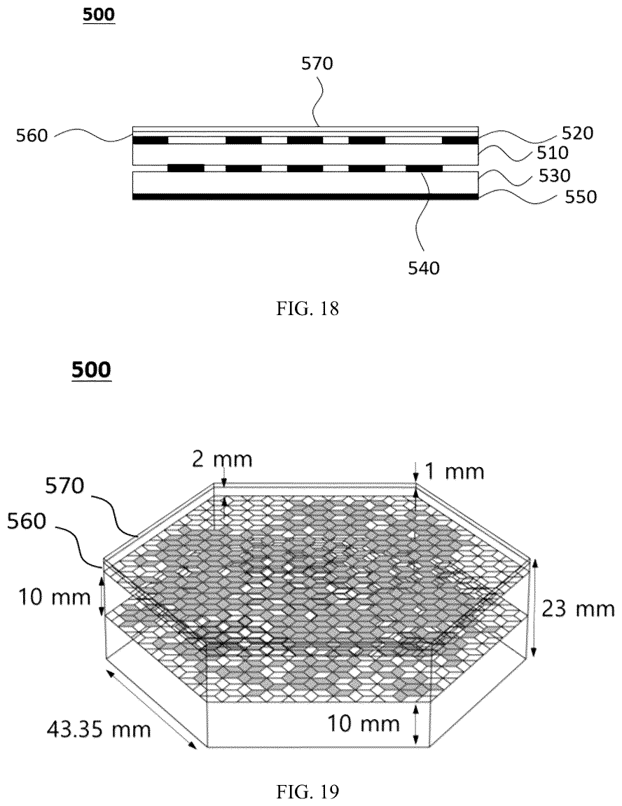

FIG. 18 is a cross-sectional view of a unit cell of an ultra-wideband electromagnetic wave absorber according to yet another preferred embodiment of the present invention.

The unit cell of the ultra-wideband electromagnetic wave absorber 500 according to yet another exemplary embodiment of the present invention may further include protective layers 560 and 570 in addition to the first dielectric layer 510, the first conductive pattern 520, the second dielectric layer 530, the second conductive pattern 540, and the reflective layer 550.

This is to increase the durability of the ultra-wideband electromagnetic wave absorber 500 by including a foam material protective layer 560 and a tempered glass protective layer 570 in addition to the configuration of the ultra-wideband electromagnetic wave absorber 500 described above for electromagnetic wave absorption.

FIG. 19 is a perspective view of a unit cell of an ultra-wideband electromagnetic wave absorber according to yet another preferred embodiment of the present invention.

It represents an example in which a foam material protective layer 560 and a tempered glass protective layer 570 are additionally coupled to the ultra-wideband electromagnetic wave absorber 500.

This increases the durability of the ultra-wideband electromagnetic wave absorber 500 by combining a protective layer to the top of the ultra-wideband electromagnetic wave absorber 500, and the protective layer may be formed of only the tempered glass protective layer 570, or may be formed by combining the foam material protective layer 560 and the tempered glass protective layer 570. In this case, the tempered glass protective layer 570 may be positioned on the upper end of the foam material protective layer 560.

The foam material protective layer 560 may minimize temperature changes when the ultra-wideband electromagnetic wave absorber 500 is exposed to an external environment. Therefore, deformation by heat may be prevented.

Since the tempered glass protective layer 570 is made of a tempered glass material with high durability, it protects the ultra-wideband electromagnetic wave absorber 500 from high-temperature and humid external environments such as rain and wind or brine, so mechanical wear and the like can be prevented.

The tempered glass protective layer 570 may be made of tempered glass having a relative dielectric constant of 4.6 and a loss tangent of 0.012, but is not limited thereto.

The foam material protective layer 560 may be thicker than the tempered glass protective layer 570. In an example, the foam material protective layer 560 may be designed to be 2 mm and the tempered glass protective layer 570 may be designed to be 1 mm, but is not limited thereto.

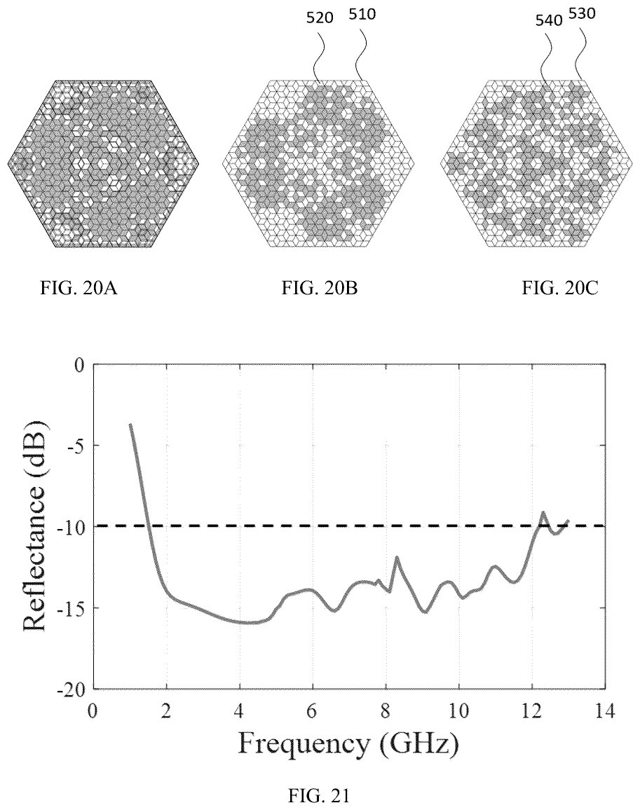

FIGS. 20A-20C show a plan view of a unit cell of an ultra-wideband electromagnetic wave absorber coupled with a protective layer according to yet another preferred embodiment of the present invention.

The example of FIGS. 20A-20C is an example of deriving an optimal conductive pattern in a state in which the protective layer is combined.

FIG. 20A shows an example in which the first conductive pattern 520 and the second conductive pattern 540 are formed by overlapping each other.

In the example where the first conductive pattern 520 and the second conductive pattern 540 overlap, it may be seen that there is still a portion in which the blank portion of the first conductive pattern 520 and the blank portion of the second conductive pattern 540 overlap.

FIG. 20B shows an example of the first dielectric layer 510, which is an upper layer, and the first conductive pattern 520 formed thereon, and FIG. 20C shows an example of the second dielectric layer 530, which is a lower layer, and the second conductive pattern 540 formed thereon.

FIG. 21 shows a simulation result of reflectance of an ultra-wideband electromagnetic wave absorber having a protective layer according to yet another preferred embodiment of the present invention.

Even when the 2 mm foam material protective layer and 1 mm tempered glass protective layer are combined, the optimal conductive pattern of the ultra-wideband electromagnetic wave absorber is derived, and a frequency band with a relative bandwidth of 153.3% with a reflectance of −10 dB or less can be seen from 1.6 GHz to 12.1 GHz.

The ultra-wideband electromagnetic wave absorber of the present invention as described above can be widely used as a material to prevent electromagnetic interference from occurring in defense stealth, wireless communication terminals, and radar, which can prevent electromagnetic wave signals reflected from our forces' weapon systems based on excellent electromagnetic wave absorption performance.

The scope of protection of the present invention is not limited to the description and expression of the embodiments explicitly described above. In addition, it is added once again that the scope of protection of the present invention may not be limited due to obvious changes or substitutions in the art of the present invention.

What is claimed is:

1. An ultra-wideband electromagnetic wave absorber having hexagonal unit cells, comprising:
a first dielectric layer having the same hexagonal unit cell shape;
a first conductive pattern formed on an upper surface of the first dielectric layer;
a second dielectric layer located below the first dielectric layer and having the same hexagonal unit cell shape as the first dielectric layer;
a second conductive pattern formed between the first dielectric layer and the second dielectric layer; and
a reflective layer formed on a lower surface of the second dielectric layer.

2. The ultra-wideband electromagnetic wave absorber according to claim 1, wherein a sheet resistance of the first conductive pattern is greater than a sheet resistance of the second conductive pattern.

3. The ultra-wideband electromagnetic wave absorber according to claim 1, wherein the first conductive pattern and the second conductive pattern are composed of carbon, indium tin oxide (ITO), or silver nanowire.

4. The ultra-wideband electromagnetic wave absorber according to claim 1, wherein the first conductive pattern and the second conductive pattern are formed by a combination of a plurality of conductive hexagonal tiles and blank hexagonal tiles.

5. The ultra-wideband electromagnetic wave absorber according to claim 1, wherein the first conductive pattern and the second conductive pattern are formed by being arranged axially symmetrically with respect to an axis connecting opposing vertices of hexagonal unit cell forming an exterior of the first dielectric layer and the second dielectric layer.

6. The ultra-wideband electromagnetic wave absorber according to claim 1, wherein only a portion of the first conductive pattern and the second conductive pattern overlap in a direction perpendicular to the first dielectric layer and the second dielectric layer.

7. The ultra-wideband electromagnetic wave absorber according to claim 1, wherein
the first conductive pattern comprises a first pattern, a second pattern, and a third pattern in a direction away from a center of the first dielectric layer, and
the second conductive pattern comprises a fourth pattern, a fifth pattern, and a sixth pattern in a direction away from a center of the second dielectric layer,
wherein a portion of the first pattern and the fourth pattern overlap in a direction perpendicular to the first dielectric layer and the second dielectric layer,
the second pattern and the fifth pattern overlap in the direction perpendicular to the first dielectric layer and the second dielectric layer, and
the third pattern and the sixth pattern are respectively formed in regions that do not overlap in the direction perpendicular to the first dielectric layer and the second dielectric layer.

8. The ultra-wideband electromagnetic wave absorber according to claim 1, wherein a length of one side of the first dielectric layer and the second dielectric layer is smaller than a length of a wavelength of a lowest frequency of an absorbed electromagnetic wave.

9. The ultra-wideband electromagnetic wave absorber according to claim 1, further comprising a protective layer formed on a top of the first conductive pattern.

10. The ultra-wideband electromagnetic wave absorber according to claim 1, wherein the reflective layer is made of metal.

11. The ultra-wideband electromagnetic wave absorber according to claim 1, wherein a difference between a dielectric constant of the first and the second dielectric layers and a dielectric constant of air is less than 10% based on the dielectric constant of the air.

12. The ultra-wideband electromagnetic wave absorber according to claim 1, wherein the first conductive pattern and the second conductive pattern are formed by a combination of a plurality of conductive rhombic tiles and blank rhombic tiles.

13. The ultra-wideband electromagnetic wave absorber according to claim 12, wherein a size of a blank region formed in the first conductive pattern or the second conductive pattern is greater than or equal to a width between two opposite sides of the blank rhombic tile.

14. The ultra-wideband electromagnetic wave absorber according to claim 12, wherein a size of a conductive region formed in the first conductive pattern or the second conductive pattern is greater than or equal to a width between two opposite sides of the conductive rhombic tile

15. The ultra-wideband electromagnetic wave absorber according to claim 12, wherein the first conductive pattern and the second conductive pattern have a blank region that is a region where the blank rhombic tiles of the first conductive pattern and the second conductive pattern overlap in a direction perpendicular to the first dielectric layer and the second dielectric layer.

16. The ultra-wideband electromagnetic wave absorber according to claim 1, wherein a thickness of the second dielectric layer is greater than or equal to a thickness of the first dielectric layer.

17. The ultra-wideband electromagnetic wave absorber according to claim 1, wherein an overall thickness of the ultra-wideband electromagnetic wave absorber is 0.11 times or less of a wavelength of a lowest frequency in a target frequency band.

18. The ultra-wideband electromagnetic wave absorber according to claim 9, wherein the protective layer is made of tempered glass.

19. The ultra-wideband electromagnetic wave absorber according to claim 18, wherein the protective layer further comprises a foam material located between an upper end of the first conductive pattern and the tempered glass.
